(19) United States
(12) Patent Application Publication
(10) Pub. No.: US 2026/0341392 A1
(43) Pub. Date: Oct. 29, 2026

(54) DATA PROCESSING METHOD AND MEMORY

(71) Applicant: Wuhan Xinxin Semiconductor Manufacturing Co., Ltd., Wuhan (CN)

(72) Inventor: Bin WU, Wuhan (CN)

(73) Assignee: Wuhan Xinxin Semiconductor Manufacturing Co., Ltd., Wuhan (CN)

(21) Appl. No.: 19/658,270

(22) Filed: Apr. 24, 2026

(30) Foreign Application Priority Data
Apr. 24, 2025 (CN) 202510525477.X

(51) Int. Cl. G11C 29/00; G11C 16/26; G11C 29/02

(52) U.S. Cl. CPC G11C 29/74; G11C 16/26; G11C 29/022

(57) ABSTRACT

The present application discloses a data processing method and a memory. The memory includes a plurality of memory rows, and each memory row includes a row of memory cells connected to a word line. The data processing method stores identical data into at least two memory rows, applies a turn-on voltage to at least one word line, and applies a read voltage to a plurality of word lines, so that the same bit line can synchronously read data from a plurality of memory cells. Even if some memory cells have defects, the bit line can still read correct data from the memory cells that have no defects, thereby reducing read errors of data and also improving the robustness of the memory cells.

### CROSS-REFERENCE TO RELATED APPLICATION

The present application claims priority to the Chinese patent application No. 202510525477.X filed with the China National Intellectual Property Administration (CNIPA) on Apr. 24, 2025, the entire content of which is incorporated into the present application by reference.

### TECHNICAL FIELD

The present application relates to the field of memory technology, and in particular to a data processing method and a memory.

### BACKGROUND

A memory typically comprises a memory array, and as the area of the memory array increases, the probability of defects occurring also increases.

When information is stored at a location having a defect, read errors are likely to occur, thereby reducing the robustness of the memory cells.

### SUMMARY

The present application provides a data processing method and a memory, in order to alleviate the technical problem of low robustness of memory cells.

In a first aspect, the present application provides a data processing method for a memory. The memory comprises a plurality of memory rows, and each memory row comprises a row of memory cells connected to a word line. The data processing method comprises: storing identical data into at least two memory rows; and applying a turn-on voltage to at least one word line, and applying a read voltage to a plurality of word lines.

In a second aspect, the present application provides a memory that executes the data processing method described above.

The data processing method and memory provided by the present application, by storing identical data into at least two memory rows, applying a turn-on voltage to at least one word line, and applying a read voltage to a plurality of word lines, enable the same bit line to synchronously read data from a plurality of memory cells. Even if some memory cells have defects, the bit line can still read correct data from the memory cells that have no defects, thereby reducing read errors of data and also improving the robustness of the memory cells.

### BRIEF DESCRIPTION OF THE DRAWINGS

The technical solutions of the present application and other beneficial effects thereof will be made apparent through the detailed description of the specific embodiments of the present application in conjunction with the accompanying drawings.

FIG. 1 is a schematic structural diagram of a memory in the related art.

FIG. 2 is a schematic structural diagram of a memory block in the related art.

FIG. 3 is a first flowchart of a data processing method provided by an embodiment of the present application.

FIG. 4 is a schematic structural diagram of configuration data provided by an embodiment of the present application.

FIG. 5 is a first schematic structural diagram of a read operation provided by an embodiment of the present application.

FIG. 6 is a second schematic structural diagram of a read operation provided by an embodiment of the present application.

FIG. 7 is a third schematic structural diagram of a read operation provided by an embodiment of the present application.

FIG. 8 is a fourth schematic structural diagram of a read operation provided by an embodiment of the present application.

FIG. 9 is a fifth schematic structural diagram of a read operation provided by an embodiment of the present application.

FIG. 10 is a second flowchart of a data processing method provided by an embodiment of the present application.

### DETAILED DESCRIPTION

The technical solutions of the embodiments of the present application will be described clearly and completely below with reference to the accompanying drawings. Obviously, the described embodiments are only a portion of the embodiments of the present application, rather than all of the embodiments. Based on the embodiments of the present application, all other embodiments obtained by a person of ordinary skill in the art without creative work fall within the scope of protection of the present application.

In addition, the terms "first" and "second" are used for descriptive purposes only and shall not be construed as indicating or implying relative importance or implicitly indicating the number of technical features specified. Accordingly, a feature defined as "first" or "second" may explicitly or implicitly include one or more of the features. In the description of the present application, the term "plurality" means two or more, unless otherwise specifically defined.

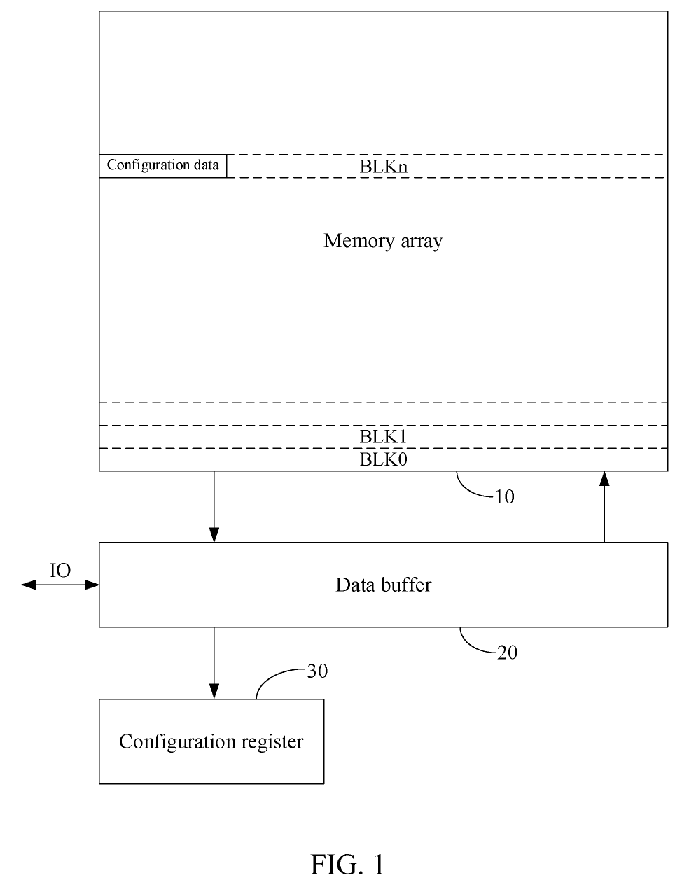

FIG. 1 is a schematic structural diagram of a memory in the related art. The memory is exemplarily a NOT AND (NAND) flash memory, and comprises a memory array 10, a data buffer 20, and a configuration register 30. The memory array 10 is connected to the data buffer 20; the data buffer 20 is connected to the configuration register 30 so as to store data from the data buffer 20 into the configuration register 30; and the data buffer 20 is connected to an input/output interface (IO) so as to enable data exchange with the outside.

The memory array 10 comprises one or more memory blocks, such as BLK0, BLK1...BLKn. Exemplarily, a flash memory performs erasing in units of memory blocks (BLK). The number of word lines (WL) connected to the same memory block is usually a plurality, for example 32, 64, 128, etc. The number of bit lines (BL) corresponding to each word line is usually a plurality as well; for example, the number of bit lines (BL) corresponding to each word line may be 2 KB, 8 KB, 16 KB, etc., wherein 1 KB equals 1024 lines.

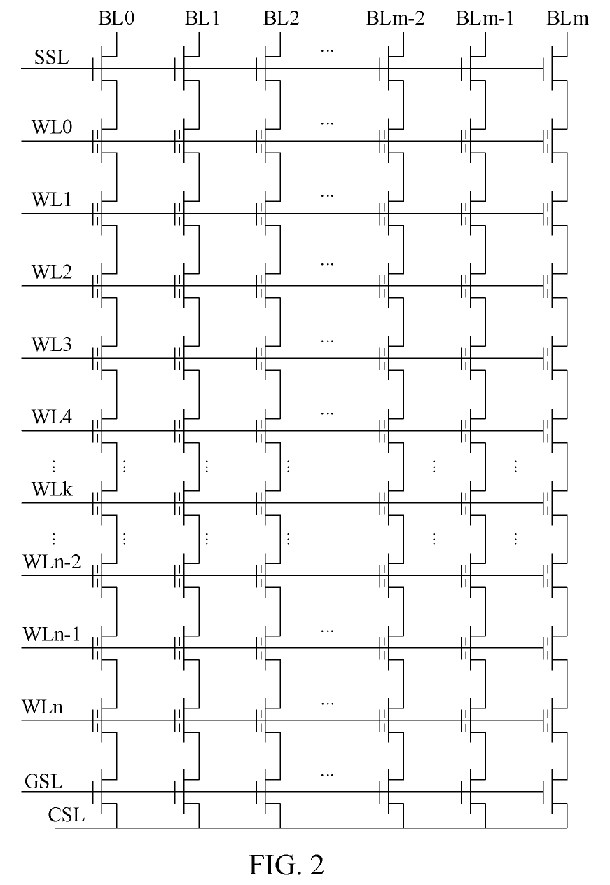

The specific structure of the memory block is as shown in FIG. 2, and comprises a plurality of transistors connected to a string select line SSL and to bit lines, a plurality of memory cells (Cell) connected to word lines, and a plurality of transistors connected to a select line GSL and a common source line CSL. The bit lines are, for example, BL0, BL1, BL2...BLm-2, BLm-1, and BLm. The word lines are, for example, WL0, WL1, WL2, WL3, WL4...WLk...WLn-2, WLn-1, and WLn. In some embodiments, the select line GSL is grounded.

In some embodiments, a flash memory needs to be configured with configuration data for a bandgap reference (BG), a charge pump (PUMP), X-direction repair (X-repair), Y-direction repair (Y-repair), a bad block (BB), etc. Such configuration data is typically stored in the configuration register 30.

After power-off, the information in the configuration register 30 is lost. Therefore, it is necessary, before shipment, to store the configuration data in the memory cells (Cell) of the flash memory as shown in FIG. 1 (data in a Cell does not disappear after power-off), and to read the data from the Cell and store the data into the configuration register 30 upon power-on.

However, the area of the memory array 10 is very large, and defects are likely to occur during the manufacturing process. When configuration data is stored at a defective location, read errors of the configuration data may occur, reducing the robustness of the configuration data and also reducing the yield.

Referring to FIGS. 1-10, the memory may comprise a plurality of memory rows, and each memory row comprises a row of memory cells connected to a word line, for example, a row of memory cells connected to WL0, a row of memory cells connected to WL1...a row of memory cells connected to WLn.

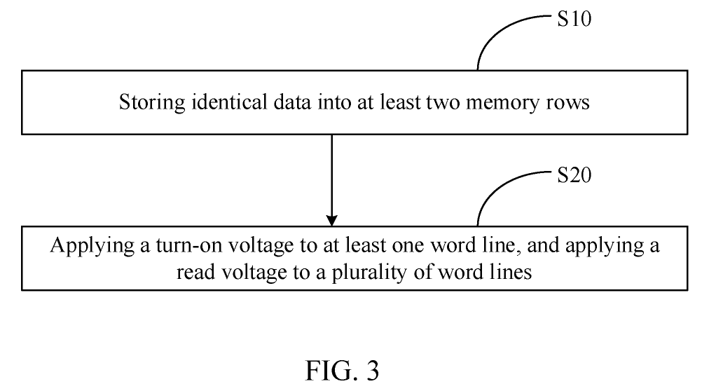

This embodiment provides a data processing method for a memory. As shown in FIG. 3, the data processing method comprises the following steps:
Step S10: storing identical data into at least two memory rows.
Step S20: applying a turn-on voltage to at least one word line, and applying a read voltage to a plurality of word lines.

It can be understood that the data processing method provided by this embodiment, by storing identical data into at least two memory rows, applying a turn-on voltage to at least one word line, and applying a read voltage to a plurality of word lines, enables the same bit line to synchronously read data from a plurality of memory cells. Even if some memory cells have defects, the bit line can still read correct data from the memory cells that have no defects, thereby reducing read errors of data and also improving the robustness of the memory cells.

It should be noted that a turn-on voltage is applied to the word lines of unselected memory cells to ensure that the unselected memory cells are fully turned on, forming a current path so that the state of the selected memory cells can be accurately detected through the bit lines. A read voltage is applied to the word line of the selected memory cells to determine the state of the selected memory cells.

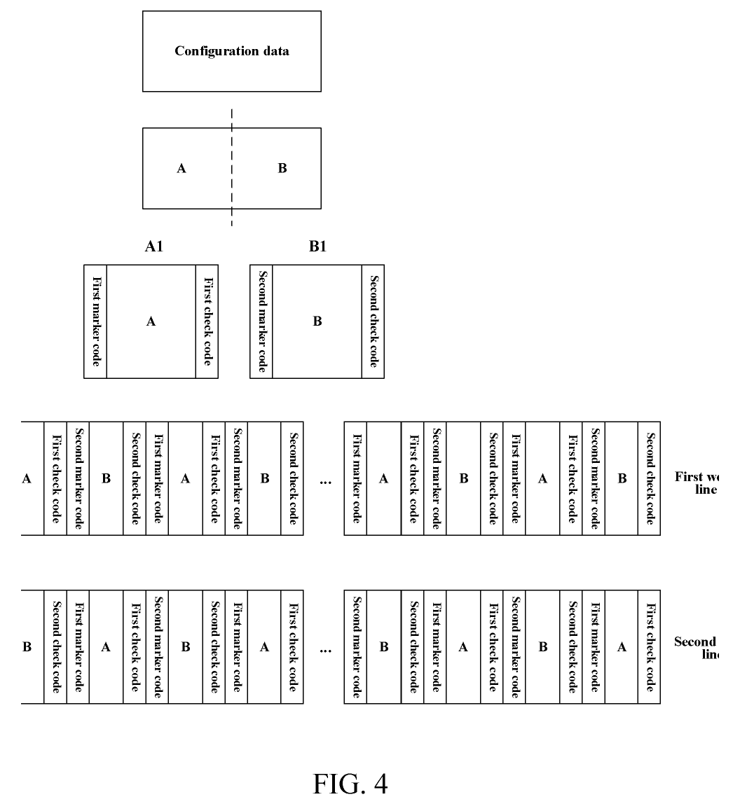

FIG. 4 is a schematic structural diagram of configuration data provided by an embodiment of the present application. Data is divided into a first data block A and a second data block B. A first marker code is provided at a data header of the first data block A, and a first check code is provided at a data tail of the first data block A. The first check code is obtained by encoding the first data block A, thereby forming a first data group A1. A second marker code is provided at a data header of the second data block B, and a second check code is provided at a data tail of the second data block B. The second check code is obtained by encoding the second data block B, thereby forming a second data group B1. The first marker code and the second marker code may be preset.

In some embodiments, the data divided into the first data block A and the second data block B is configuration data.

In some embodiments, the word lines comprise first-type word lines and third-type word lines. The plurality of memory rows comprise first-type memory rows for storing first type data and third-type memory rows for storing third type data. Each of the first-type memory rows is connected to one of the first-type word lines, and each of the third-type memory rows is connected to one of the third-type word lines. The data processing method further comprises: applying a turn-on voltage to the third-type word line, and applying a read voltage to a number of the first-type word lines.

It should be noted that in this embodiment, the first-type memory rows may store alternating first data groups A1 and second data groups B1 in sequence, or alternatively may store alternating second data groups B1 and first data groups A1 in sequence. In some of the embodiments, the third-type memory rows and the third-type word lines are optional.

In some of the embodiments, the word lines comprise first-type word lines and second-type word lines. The plurality of memory rows comprise first-type memory rows and second-type memory rows. Each of the first-type memory rows is connected to one of the first-type word lines, and each of the second-type memory rows is connected to one of the second-type word lines. The data processing method further comprises: applying a turn-on voltage to one of the first-type word lines and the second-type word lines, and applying a read voltage to another of the first-type word lines and the second-type word lines.

It should be noted that the plurality of first-type memory rows may be adjacent or non-contiguous. The plurality of second-type memory rows may be adjacent or non-contiguous.

As shown in FIG. 4, each of the first-type memory rows stores alternating first data groups A1 and second data groups B1 in sequence, and each of the second-type memory rows stores alternating second data groups B1 and first data groups A1 in sequence. In some embodiments, in response to that the first data groups A1 and the second data groups B1 are configuration data, the data needs to be stored in the memory array 10 before shipment. In other embodiments, if the first data groups A1 and the second data groups B1 are user data, there is no restriction on when the data is stored in the memory array 10.

Each of the first check codes in FIG. 4 is not necessarily identical; each first check code is computed based on each respective data block, and the same applies to the second check codes. Each of the first marker codes may be equal to one another, and each of the second marker codes may be equal to one another.

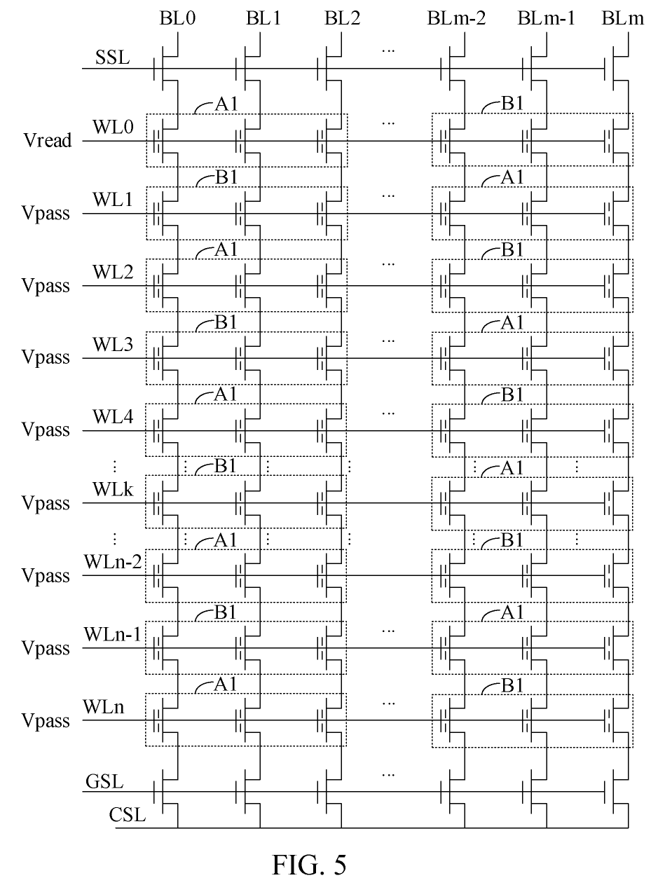

FIG. 5 is a first schematic structural diagram of a read operation provided by an embodiment of the present application. The memory rows connected to WL0, WL2, WL4...WLn-2, and WLn may exemplarily be first-type memory rows, and each of the first-type memory rows stores alternating first data groups A1 and second data groups B1 in sequence. The memory rows connected to WL1, WL3, WLk...WLn-1 may exemplarily be second-type memory rows, and each of the second-type memory rows stores alternating second data groups B1 and first data groups A1 in sequence.

By applying a read voltage Vread to WL0 and applying a turn-on voltage Vpass to the other word lines, for example WL1, WL2, WL3, WL4...WLk...WLn-2, WLn-1, and WLn, the data in the memory row connected to WL0 can be read out and stored into the data buffer 20 via each bit line, namely BL0, BL1, BL2...BLm-2, BLm-1, and BLm.

In some embodiments, the first-type memory rows may be memory cells in even-numbered rows, and the second-type memory rows may be memory cells in odd-numbered rows.

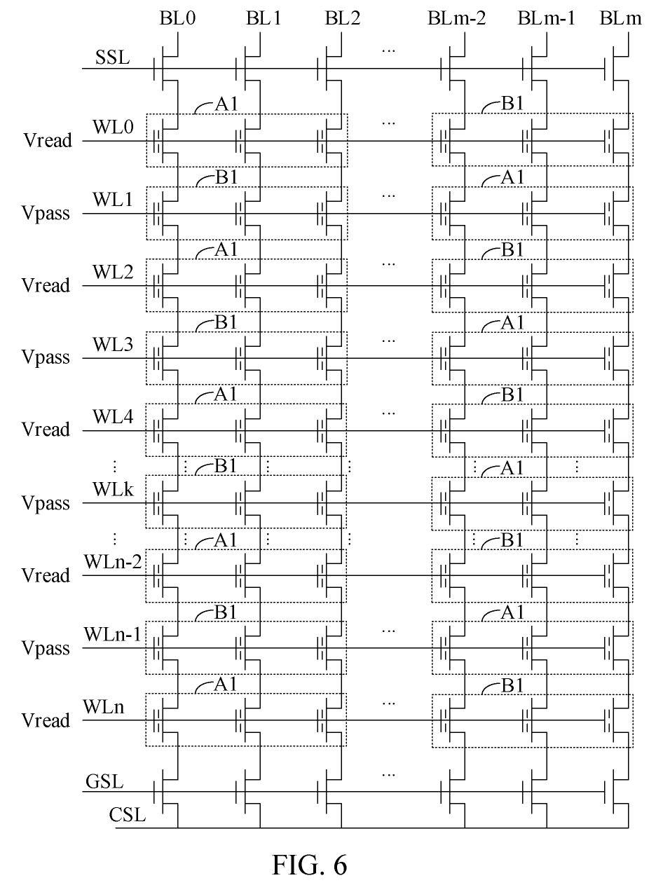

FIG. 6 is a second schematic structural diagram of a read operation provided by an embodiment of the present application. Different from FIG. 5, by applying a read voltage Vread to WL0, WL2, WL4...WLn-2, and WLn, and applying a turn-on voltage Vpass to the other word lines, for example WL1, WL3, WLk...WLn-1, the data in each memory row connected to WL0, WL2, WL4...WLn-2, and WLn can be read out and stored into the data buffer 20 via each bit line, namely BL0, BL1, BL2...BLm-2, BLm-1, and BLm.

As can be seen from FIG. 6, the data of a plurality of memory cells in a first column from left to right among the memory cells connected to WL0, WL2, WL4...WLn-2, and WLn represents 1 bit of data read from BL0. In this way, even if some of the memory cells have defects, the correctness of the read data can be ensured, thereby improving the robustness of the memory cells.

In the related art, only the data of one memory cell is read at a time. If this data changes, the read current will change significantly, thereby causing the read data to also be incorrect.

For this embodiment, the memory cells in even-numbered rows in the first column store identical data. In this case, by simultaneously reading a plurality of identical data from a plurality of serially connected memory cells, even if some data changes due to the above-mentioned defects, since the memory cells are serially connected, the change in the read current is not large, thereby ensuring the correctness of the read data.

The defect referred to above means that the data stored in a memory cell has changed, and when a turn-on voltage is applied to the memory cell, the memory cell is in an on state rather than an off state.

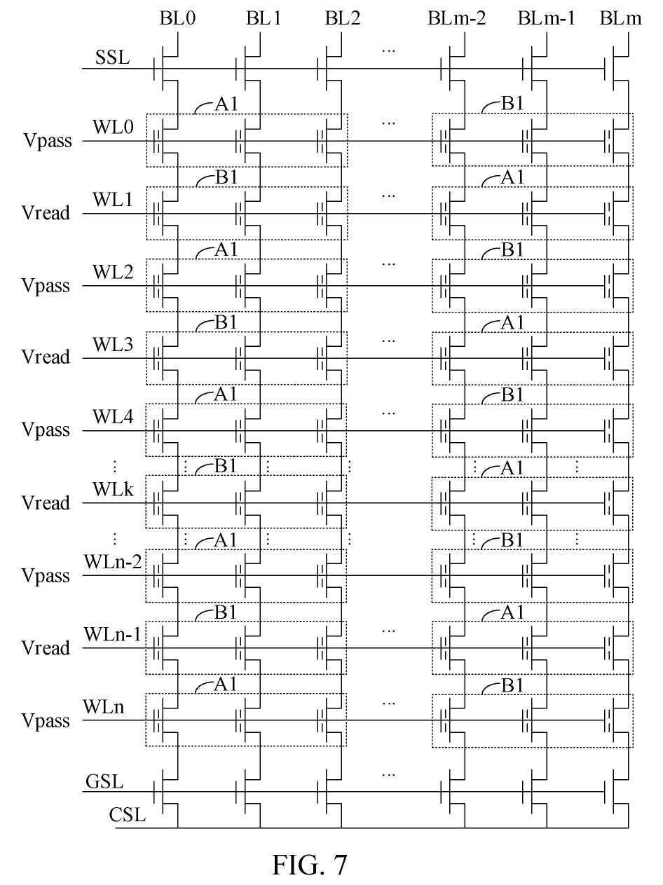

FIG. 7 is a third schematic structural diagram of a read operation provided by an embodiment of the present application. Different from FIG. 6, by applying a turn-on voltage Vpass to WL0, WL2, WL4...WLn-2, and WLn, and applying a read voltage Vread to the other word lines, for example WL1, WL3, WLk...WLn-1, the data in each memory row connected to WL1, WL3, WLk...WLn-1 can be read out and stored into the data buffer 20 via each bit line, namely BL0, BL1, BL2...BLm-2, BLm-1, and BLm.

As can be seen from FIG. 7, the data of a plurality of memory cells in a first column from left to right among the memory cells connected to WL1, WL3, WLk...WLn-1 represents 1 bit of data read from BL0. In this way, even if some of the memory cells have defects, the correctness of the read data can be ensured, thereby improving the robustness of the memory cells.

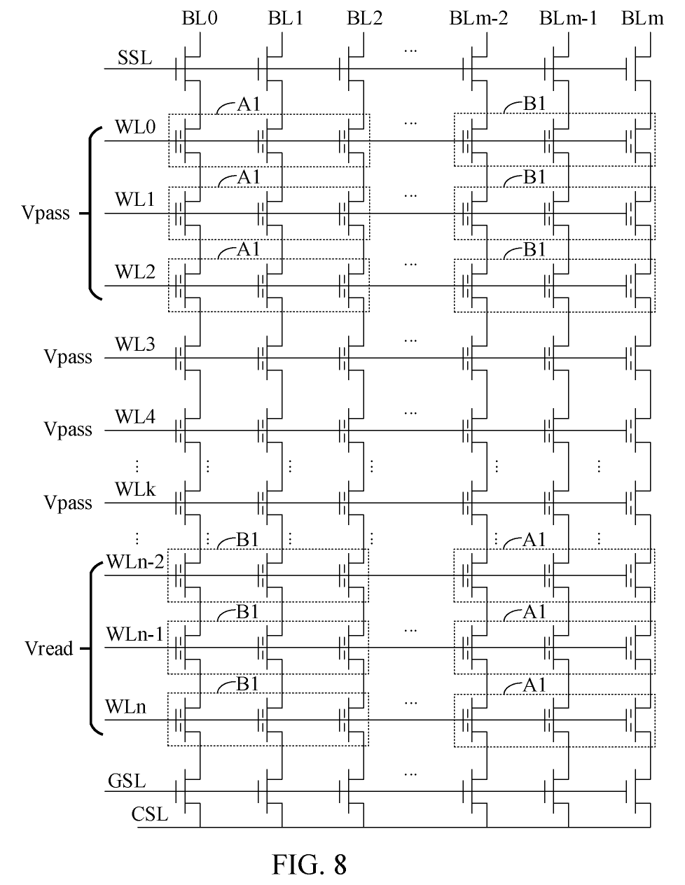

FIG. 8 is a fourth schematic structural diagram of a read operation provided by an embodiment of the present application. The memory rows connected to WL0, WL1, and WL2 may exemplarily be first-type memory rows, and each of the first-type memory rows stores alternating first data groups A1 and second data groups B1 in sequence. The memory rows connected to WLn-2, WLn-1, and WLn may exemplarily be second-type memory rows, and each of the second-type memory rows stores alternating second data groups B1 and first data groups A1 in sequence. The memory rows connected to a third-type word lines, for example WL3, WL4...WLk, may exemplarily be third-type memory rows, and the third-type memory rows may be used to store user data other than configuration data.

By applying a turn-on voltage Vpass to WL0, WL1, WL2, WL3, WL4...WLk and applying a read voltage Vread to WLn-2, WLn-1, and WLn, the data in each memory row connected to WLn-2, WLn-1, and WLn can be read out and stored into the data buffer 20 via each bit line, namely BL0, BL1, BL2...BLm-2, BLm-1, and BLm.

As can be seen from FIG. 8, the data of a plurality of memory cells in a first column from left to right among the memory cells connected to WLn-2, WLn-1, and WLn represents 1 bit of data read from BL0. In this way, even if some of the memory cells have defects, the correctness of the read data can be ensured, thereby improving the robustness of the memory cells.

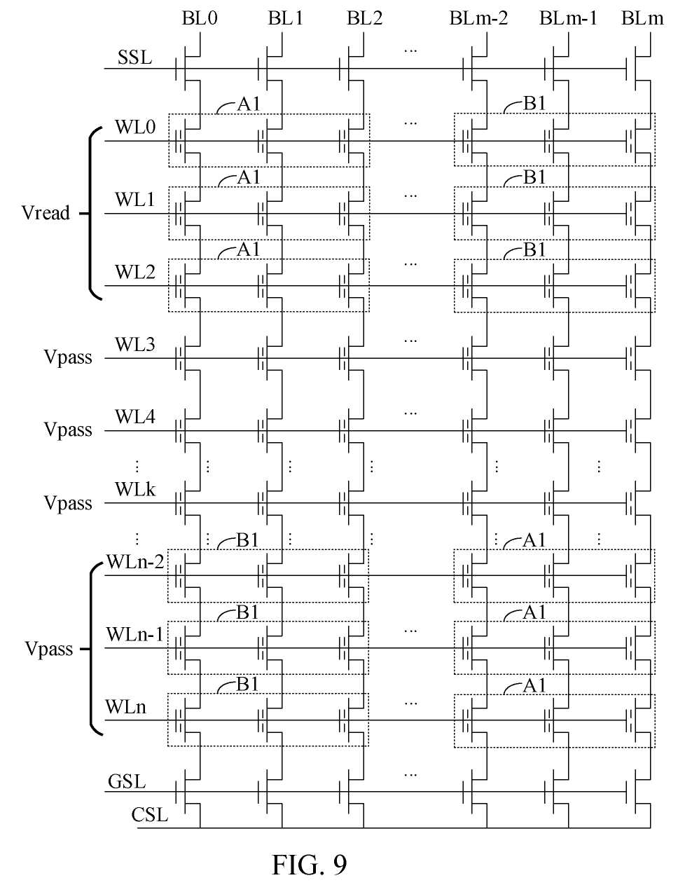

FIG. 9 is a fifth schematic structural diagram of a read operation provided by an embodiment of the present application. Different from FIG. 8, by applying a read voltage Vread to WL0, WL1, and WL2, and applying a turn-on voltage Vpass to WL3, WL4...WLk...WLn-2, WLn-1, and WLn, the data in each memory row connected to WL0, WL1, and WL2 can be read out and stored into the data buffer 20 via each bit line, namely BL0, BL1, BL2...BLm-2, BLm-1, and BLm.

As can be seen from FIG. 9, the data of a plurality of memory cells in a first column from left to right among the memory cells connected to WL0, WL1, and WL2 represents 1 bit of data read from BL0. In this way, even if some of the memory cells have defects, the correctness of the read data can be ensured, thereby improving the robustness of the memory cells.

In summary, the memory cells connected to the word lines to which the turn-on voltage Vpass is applied can function as transfer transistors. As the number of word lines to which the turn-on voltage Vpass is applied increases, not only can the resistance on the corresponding bit lines be reduced, but also the number of word lines to which the read voltage Vread is applied is reduced.

In some of the embodiments, the data processing method further comprises: reading out at least one first data group A1 and at least one second data group B1 into the data buffer 20; searching the data buffer 20 for a correct one of the first data blocks A and a correct one of the second data blocks B; and storing the correct one of the first data blocks A and the correct one of the second data blocks B into the configuration register 30.

It should be noted that as the number of first data groups A1 and second data groups B1 read out increases, the correctness of the read data can be further ensured, thereby improving the robustness of the memory cells.

In some of the embodiments, the searching the data buffer 20 for a correct one of the first data blocks A and a correct one of the second data blocks B comprises the following steps:

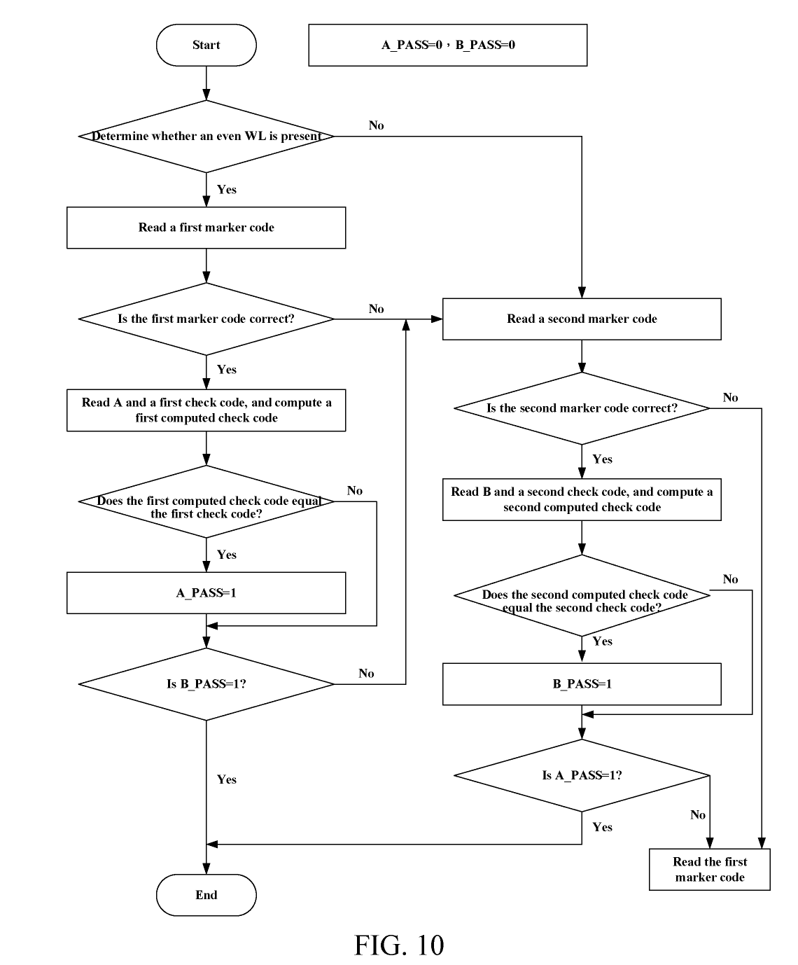

As shown in FIG. 10, in response to powering on, which corresponds to the start, resetting a first status code (A_PASS=0) and a second status code (B_PASS=0).

Determining a judgment result of whether a read voltage is applied to a number of the first-type word lines. This corresponds to the step of determining whether even WLs are present in FIG. 10. The even WLs may exemplarily be WL0, WL2, WL4...WLn-2, and WLn in FIGS. 5-9, and correspondingly the odd WLs may exemplarily be WL1, WL3, WLk...WLn-1 in FIGS. 5-9.

Searching for a correct one of the first data blocks A and a correct one of the second data blocks B based on the judgment result, the first status code, and the second status code. Some of the first data blocks A and/or second data blocks B may have already encountered errors when being read out from the memory array 10, possibly due to defects. Therefore, storing a plurality of first data blocks A and a plurality of second data blocks B in the data buffer 20 can improve the chance of finding a correct first data block A and a correct second data block B.

In some of the embodiments, the searching for a correct one of the first data blocks A and a correct one of the second data blocks B based on the judgment result, the first status code, and the second status code comprises: determining the first status code and the second status code based on the judgment result; and searching for a correct one of the first data blocks A and a correct one of the second data blocks B according to the first status code and the second status code.

It should be noted that in this embodiment, a correct one of the first data blocks A and a correct one of the second data blocks B can be found based on the judgment result alone, which simplifies the processing procedure.

In some of the embodiments, the determining the first status code and the second status code based on the judgment result comprises: determining the first status code based on the judgment result and a verification result of the first data group A1; and determining the second status code based on the judgment result and a verification result of the second data group B1.

It should be noted that a verification result is used to determine whether the corresponding data group has been affected by a defect and has encountered an error.

In some of the embodiments, the determining the first status code based on the judgment result and the verification result of the first data group A1, as shown in FIG. 10, comprises the following steps:

In response to that the judgment result indicates that a read voltage is applied to a number of the first-type word lines, or in response to that the second marker code is incorrect, or in response to that the first status code equals data "0", reading the first marker code.

Determining whether the first marker code is correct.

It should be noted that the first marker code and the second marker code are both used to improve the speed of finding a correct one of the first data blocks A and a correct one of the second data blocks B, so as to reduce the search time. That is, in response to that the first marker code or the second marker code is incorrect, the processing of the current data group is abandoned and processing proceeds to the next data group.

In response to that the first marker code is correct, reading the first data block A and the first check code, and computing a first computed check code for the first data block A. The first computed check code is obtained by encoding the first data block A stored in the data buffer 20.

Determining whether the first computed check code equals the first check code. This can be used to verify whether the first data block A has encountered an error due to a defect.

In response to that the first computed check code equals the first check code, determining the first status code as data "1". The fact that the first computed check code equals the first check code indicates that no error has occurred in the first data block A. At this point, the first marker code, the first data block A, and the first check code in the first data group A1 have all passed verification, indicating that a correct one of the first data blocks A has been found.

In some of the embodiments, the searching for a correct one of the first data blocks A and a correct one of the second data blocks B according to the first status code and the second status code, as shown in FIG. 10, comprises the following steps:

After the first status code is determined as data "1", or after the first computed check code does not equal the first check code, determining whether the second status code equals data "1".

In response to that the second status code equals data "1", determining that a correct one of the first data blocks A and a correct one of the second data blocks B have been found.

The fact that the second status code equals data "1" indicates that a correct one of the second data blocks B has been found. At this point, since the search objective has been completed, power-on can be concluded.

In some of the embodiments, the determining the second status code based on the judgment result and the verification result of the second data group B1, as shown in FIG. 10, comprises the following steps:

In response to that the judgment result indicates that a read voltage is not applied to a number of the first-type word lines, or in response to that the first marker code is incorrect, or in response to that the second status code equals data "0", reading the second marker code.

Determining whether the second marker code is correct; in response to that the second marker code is correct, reading the second data block B and the second check code, and computing a second computed check code for the second data block B. The second computed check code is obtained by encoding the second data block B stored in the data buffer 20.

Determining whether the second computed check code equals the second check code. This can be used to verify whether the second data block B has encountered an error due to a defect.

In response to that the second computed check code equals the second check code, determining the second status code as data "1". The fact that the second computed check code equals the second check code indicates that no error has occurred in the second data block B. At this point, the second marker code, the second data block B, and the second check code in the second data group B1 have all passed verification, indicating that a correct one of the second data blocks B has been found.

In some of the embodiments, the searching for a correct one of the first data blocks A and a correct one of the second data blocks B according to the first status code and the second status code, as shown in FIG. 10, further comprises the following steps:

After the second status code is determined as data "1", or after the second computed check code does not equal the second check code, determining whether the first status code equals data "1".

In response to that the first status code equals data "1", determining that a correct one of the first data blocks A and a correct one of the second data blocks B have been found. The fact that the first status code equals data "1" indicates that a correct one of the first data blocks A has been found. At this point, since the search objective has been completed, power-on can be concluded.

In some of the embodiments, this embodiment further provides a memory, and the memory executes the data processing method described above.

It can be understood that, since the memory provided by this embodiment executes the data processing method described above, by storing identical data into at least two memory rows, applying a turn-on voltage to at least one word line, and applying a read voltage to a plurality of word lines, the same bit line can synchronously read data from a plurality of memory cells. Even if some memory cells have defects, the bit line can still read correct data from the memory cells that have no defects, thereby reducing read errors of data and also improving the robustness of the memory cells.

It should be noted that the memory described above may be, but is not limited to, a NAND flash memory. Other memory chips to which the present application is applicable may also be used, for example, memory chips that do not comprise at least one of the string select line SSL, the select line GSL, and the common source line CSL and the transistors connected thereto.

In the above embodiments, the descriptions of each embodiment each have their own emphasis. For portions not described in detail in a given embodiment, reference may be made to the related descriptions of other embodiments.

The data processing method and memory provided by the embodiments of the present application have been described in detail above. Specific examples have been used in this document to illustrate the principles and embodiments of the present application. The description of the above embodiments is only intended to help in understanding the technical solutions of the present application and their core ideas. A person of ordinary skill in the art should understand that modifications may still be made to the technical solutions described in the foregoing embodiments, or equivalent substitutions may be made to some of the technical features thereof; and such modifications or substitutions do not cause the essence of the corresponding technical solutions to depart from the scope of the technical solutions of the embodiments of the present application.

1. A data processing method for a memory, wherein the memory comprises a plurality of memory rows, each of the plurality of memory rows comprises a row of memory cells connected to a word line, and the data processing method comprises:
storing identical data into at least two of the plurality of memory rows; and
applying a turn-on voltage to at least one of the word lines, and applying a read voltage to a number of the word lines.

2. The data processing method according to claim 1, wherein the word lines comprise first-type word lines and third-type word lines, the plurality of memory rows comprise first-type memory rows for storing first type data and third-type memory rows for storing third type data, each of the first-type memory rows is connected to one of the first-type word lines, each of the third-type memory rows is connected to one of the third-type word lines, and the data processing method further comprises:
applying a turn-on voltage to the third-type word line, and applying a read voltage to a number of the first-type word lines.

3. The data processing method according to claim 1, wherein the word lines comprise first-type word lines and second-type word lines, the plurality of memory rows comprise first-type memory rows and second-type memory rows, each of the first-type memory rows is connected to one of the first-type word lines, each of the second-type memory rows is connected to one of the second-type word lines, and the data processing method further comprises:
applying a turn-on voltage to one of the first-type word lines and the second-type word lines, and applying a read voltage to another of the first-type word lines and the second-type word lines.

4. The data processing method according to claim 3, wherein the data processing method further comprises:
configuring each of the first-type memory rows to store alternating first data groups and second data groups in sequence, and configuring each of the second-type memory rows to store alternating second data groups and first data groups in sequence.

5. The data processing method according to claim 4, wherein the data processing method further comprises:
configuring each of the first data groups to comprise a first marker code located at a data header, a first check code located at a data tail, and a first data block located between the data header and the data tail; and
configuring each of the second data groups to comprise a second marker code located at a data header, a second check code located at a data tail, and a second data block located between the data header and the data tail.

6. The data processing method according to claim 5, wherein the data processing method further comprises:
reading out at least one of the first data groups and at least one of the second data groups into a data buffer;
searching the data buffer for a correct one of the first data blocks and a correct one of the second data blocks; and
storing the correct one of the first data blocks and the correct one of the second data blocks into a configuration register.

7. The data processing method according to claim 6, wherein the searching the data buffer for a correct one of the first data blocks and a correct one of the second data blocks comprises:
in response to powering on, resetting a first status code and a second status code;
determining a judgment result of whether a read voltage is applied to a number of the first-type word lines; and
searching for a correct one of the first data blocks and a correct one of the second data blocks based on the judgment result, the first status code, and the second status code.

8. The data processing method according to claim 7, wherein the searching for a correct one of the first data blocks and a correct one of the second data blocks based on the judgment result, the first status code, and the second status code comprises:
determining the first status code and the second status code based on the judgment result; and
searching for a correct one of the first data blocks and a correct one of the second data blocks according to the first status code and the second status code.

9. The data processing method according to claim 8, wherein the determining the first status code and the second status code based on the judgment result comprises:
determining the first status code based on the judgment result and a verification result of the first data group; and
determining the second status code based on the judgment result and a verification result of the second data group.

10. The data processing method according to claim 9, wherein the determining the first status code based on the judgment result and the verification result of the first data group comprises:
in response to that the judgment result indicates that a read voltage is applied to a number of the first-type word lines, or in response to that the second marker code is incorrect, or in response to that the first status code equals data "0", reading the first marker code;
determining whether the first marker code is correct;
in response to that the first marker code is correct, reading the first data block and the first check code, and computing a first computed check code for the first data block;
determining whether the first computed check code equals the first check code; and
in response to that the first computed check code equals the first check code, determining the first status code as data "1".

11. The data processing method according to claim 10, wherein the searching for a correct one of the first data blocks and a correct one of the second data blocks according to the first status code and the second status code comprises:
after the first status code is determined as data "1", or after the first computed check code does not equal the first check code, determining whether the second status code equals data "1"; and
in response to that the second status code equals data "1", determining that a correct one of the first data blocks and a correct one of the second data blocks have been found.

12. The data processing method according to claim 11, wherein the determining the second status code based on the judgment result and the verification result of the second data group comprises:
in response to that the judgment result indicates that a read voltage is not applied to a number of the first-type word lines, or in response to that the first marker code is incorrect, or in response to that the second status code equals data "0", reading the second marker code;
determining whether the second marker code is correct;
in response to that the second marker code is correct, reading the second data block and the second check code, and computing a second computed check code for the second data block;
determining whether the second computed check code equals the second check code; and
in response to that the second computed check code equals the second check code, determining the second status code as data "1".

13. The data processing method according to claim 12, wherein the searching for a correct one of the first data blocks and a correct one of the second data blocks according to the first status code and the second status code further comprises:
after the second status code is determined as data "1", or after the second computed check code does not equal the second check code, determining whether the first status code equals data "1"; and
in response to that the first status code equals data "1", determining that a correct one of the first data blocks and a correct one of the second data blocks have been found.

14. A memory, executing a data processing method, wherein the memory comprises a plurality of memory rows, each of the plurality of memory rows comprises a row of memory cells connected to a word line, and the data processing method comprises:
storing identical data into at least two of the plurality of memory rows; and
applying a turn-on voltage to at least one of the word lines, and applying a read voltage to a number of the word lines.

15. The memory according to claim 14, wherein the word lines comprise first-type word lines and third-type word lines, the plurality of memory rows comprise first-type memory rows for storing first type data and third-type memory rows for storing third type data, each of the first-type memory rows is connected to one of the first-type word lines, each of the third-type memory rows is connected to one of the third-type word lines, and the data processing method further comprises:
applying a turn-on voltage to the third-type word line, and applying a read voltage to a number of the first-type word lines.

16. The memory according to claim 14, wherein the word lines comprise first-type word lines and second-type word lines, the plurality of memory rows comprise first-type memory rows and second-type memory rows, each of the first-type memory rows is connected to one of the first-type word lines, each of the second-type memory rows is connected to one of the second-type word lines, and the data processing method further comprises:
applying a turn-on voltage to one of the first-type word lines and the second-type word lines, and applying a read voltage to another of the first-type word lines and the second-type word lines.

17. The memory according to claim 16, wherein the data processing method further comprises:
configuring each of the first-type memory rows to store alternating first data groups and second data groups in sequence, and configuring each of the second-type memory rows to store alternating second data groups and first data groups in sequence.

18. The memory according to claim 17, wherein the data processing method further comprises:
configuring each of the first data groups to comprise a first marker code located at a data header, a first check code located at a data tail, and a first data block located between the data header and the data tail; and
configuring each of the second data groups to comprise a second marker code located at a data header, a second check code located at a data tail, and a second data block located between the data header and the data tail.

19. The memory according to claim 18, wherein the data processing method further comprises:
reading out at least one of the first data groups and at least one of the second data groups into a data buffer;
searching the data buffer for a correct one of the first data blocks and a correct one of the second data blocks; and
storing the correct one of the first data blocks and the correct one of the second data blocks into a configuration register.

20. The memory according to claim 19, wherein the searching the data buffer for a correct one of the first data blocks and a correct one of the second data blocks comprises:
in response to powering on, resetting a first status code and a second status code;
determining a judgment result of whether a read voltage is applied to a number of the first-type word lines; and
searching for a correct one of the first data blocks and a correct one of the second data blocks based on the judgment result, the first status code, and the second status code.
